(19) United States
(12) Patent Application Publication
(10) Pub. No.: US 2005/0205013 A1
(43) Pub. Date: Sep. 22, 2005

(54) Plasma processing apparatus and plasma processing method

(75) Inventors: Toshio Nakanishi, Hyogo (JP); Tatsuo Nishita, Hyogo (JP); Shigenori Ozaki, Hyogo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: TOKYO ELECTRON LIMITED.

(21) Appl. No.: 11/131,215

(22) Filed: May 18, 2005

Related U.S. Application Data
(63) Continuation-in-part of application No. PCT/JP03/14797, filed on Nov. 20, 2003.

(30) Foreign Application Priority Data
Nov. 20, 2002 (JP) JP2002-335893

(51) Int. Cl. C23C 16/00

(52) U.S. Cl. 118/723 AN; 118/722; 156/345.34; 156/345.41

(57) ABSTRACT

According to the present invention, when nitridation processing or oxidation processing is applied to a surface of a substrate, a partition plate having openings is disposed between a plasma generating part and the substrate, and electron density on the surface of the substrate is controlled to be 1e+7 (electrons/cm³) to 5e+9 (electrons/cm³). According to the present invention, deterioration of the substrate and a nitride film is effectively suppressed.

This is a continuation in part of PCT Application No. PCT/JP03/14797, filed Nov. 20, 2003, which claims the benefit of a Japanese Patent Application No. 2002-335893, filed Nov. 20, 2002, all of which are incorporated herein by reference.

### BACKGROUND OF THE INVENTION

1. Field of the Invention

The present invention relates to a plasma processing apparatus and a plasma processing method that apply nitridation processing or oxidation processing to a substrate by using plasma.

2. Description of the Related Art

When nitridation processing is applied to a silicon substrate by using plasma, nitrogen-containing gas such as nitrogen gas, gas of nitrogen and hydrogen, or NH₃ gas is introduced into plasma of rare gas such as argon or krypton excited by, for example, a microwave. Consequently, N radicals or NH radicals are generated so that a surface of a silicon oxide film is turned into a nitride film. Another method available is a method of directly nitriding a surface of a silicon substrate by microwave plasma.

According to conventional apparatuses and conventional methods, a base film (Si, SiO₂) or a deposited film (SiN) is sometimes damaged by ions entering a surface of a silicon oxide film (silicon substrate). The damage of the film deteriorates device(transistor) on the substrate, which sometimes causes problems such as deterioration in transistor characteristics ascribable to an increase in leakage current and deterioration in interface characteristics.

There has sometimes been another problem of an excessive increase in thickness of a silicon nitride film due to diffusion of oxygen to an interface between a silicon oxide film and the silicon nitride film.

### SUMMARY OF THE INVENTION

The present invention was made in view of the circumstances described above, and it is a first object of the present invention to provide a plasma processing apparatus and a plasma processing method capable of effectively suppressing deterioration of, for example, a silicon substrate (silicon oxide film) and a nitride film.

It is a second object of the present invention to provide a plasma processing apparatus and a plasma processing method capable of effectively suppressing an increase in thickness of a silicon nitride film.

In order to achieve the above objects, a plasma processing apparatus according to a first aspect of the present invention includes a partition plate provided between a plasma generating part and a substrate and having openings.

Thus providing the partition plate in a process vessel lowers temperature of electrons reaching the substrate, resulting in a reduction in ion energy, so that damage to the substrate and a nitride film itself can be effectively suppressed. Moreover, the velocity of gas reaching the substrate after transmitting through the openings of the partition plate becomes higher on the substrate, resulting in a lowered partial pressure of oxygen on the surface of the substrate, so that an amount of oxygen getting out of the nitride film to a substrate surface side increases. As a result, the increase in the thickness of the nitride film can be effectively suppressed.

The partition plate having a large number of the openings arranged to face the substrate is preferably used. In this case, preferably, an open area of each of the openings is, for example, 3 mm² to 450 mm², the partition plate is 3 mm to 7 mm in thickness, and the partition plate is positioned 20 mm to 50 mm above a surface of the substrate.

As for size of the openings, the openings may be all equal in size, but the openings in a center portion of the partition plate may be set smaller in diameter than the openings positioned on an outer side of the center portion. This can suppress the increase in thickness of the nitride film in the center portion of the substrate more than in the position on the outer side thereof. The diameter of each of the openings in the center portion and the diameter of each of the openings positioned on the outer side of the center portion can be set to, for example, 9.5 mm and 10 mm respectively. Moreover, when the diameter of each of the openings in the center portion of the partition plate is set larger than the diameter of each of the openings positioned on the outer side of the center portion, it is possible to promote the increase in the thickness of the nitride film in the center portion of the substrate more than in the position on the outer side thereof.

The present invention is also applicable to an apparatus applying oxidation processing by using plasma. Specifically, in a plasma processing apparatus applying oxidation processing to a substrate disposed in a process vessel by using plasma, it can be also proposed that the apparatus includes a partition plate provided between a plasma generating part and the substrate and having openings. Also in this case, the openings in a center portion of the partition plate may be set smaller in diameter than the openings positioned on an outer side of the center portion. The diameter of each of the openings in the center portion and the diameter of each of the openings positioned on the outer side of the center portion may be set to, for example, 2 mm and 2.5 mm respectively. Moreover, conversely, the openings in the center portion of the partition plate may be set larger in diameter than the openings positioned on the outer side of the center portion.

In a plasma processing method according to another aspect of the present invention, electron density on a surface of a substrate is controlled to be 1e+7 (electrons/cm³) to 5e+9 (electrons/cm³). As described above, lowering ion energy and ion density on the substrate makes it possible to effectively suppress damage to the substrate and the nitride film.

Further, in a plasma processing method according to still another aspect of the present invention, gas velocity on a surface of a substrate is controlled to be 1e⁻² (m/sec) to 1e+1 (m/sec). As described above, an increase in gas velocity on the substrate results in a lowered partial pressure of oxygen on the surface of the substrate, so that an amount of oxygen getting out of the nitride film to the substrate surface side increases. As a result, an increase in the thickness of the nitride film can be effectively suppressed.

### BRIEF DESCRIPTION OF THE DRAWINGS

FIG. 1 is a schematic view showing a structure of a plasma processing apparatus according to an embodiment of the present invention;

FIG. 2 is a plane view of a plasma baffle plate used in the embodiment;

FIG. 3(A) to FIG. 3(C) are schematic views showing part of processes of plasma processing in the embodiment;

FIG. 4 is a graph showing how a ratio of nitrogen contents in a film changes in accordance with a lapse of time of nitridation processing;

FIG. 5 is a graph showing how electron density changes under varied process pressure;

FIG. 6 is a graph showing how electron temperature changes under varied process pressure; and

FIG. 7 is a plane view of a plasma baffle plate in which openings in a center portion and those on an outer periphery thereof are different in size.

### DETAILED DESCRIPTION OF THE INVENTION

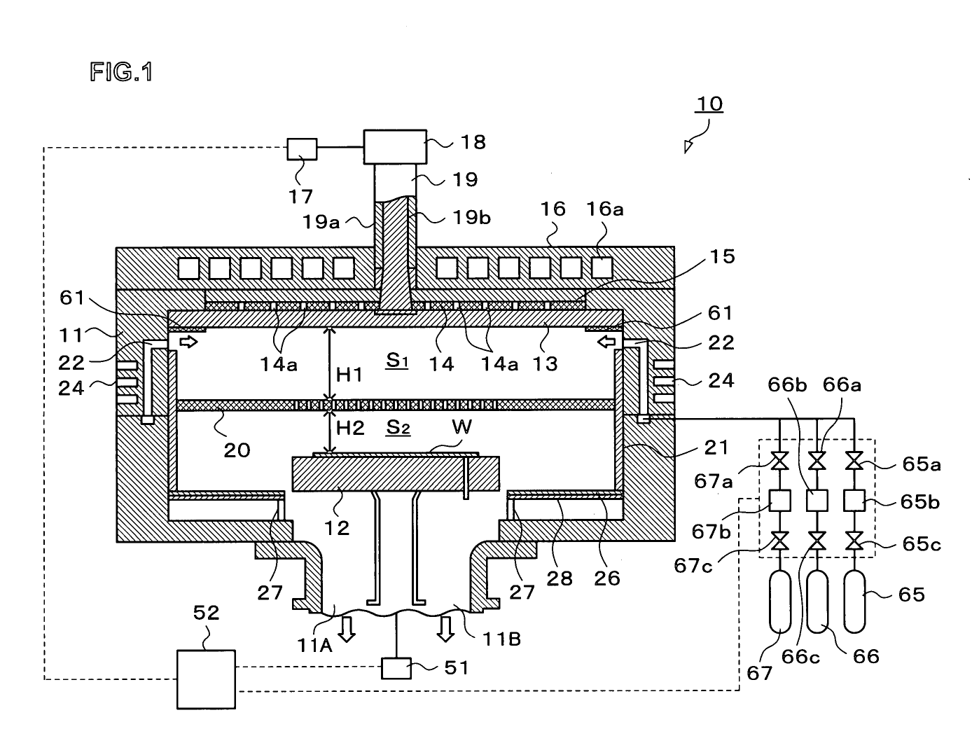

FIG. 1 shows a schematic structure of a plasma processing apparatus 10 according to an embodiment of the present invention. The plasma processing apparatus 10 has a process vessel 11 in which a substrate holding table 12 for holding a silicon wafer W as a substrate to be processed is formed, and air (gas) inside the process vessel 11 is exhausted by an exhaust device 51 through exhaust ports 11A, 11B. Note that the substrate holding table 12 has a heater function for heating the silicon wafer W (a heater itself is not shown).

The process vessel 11 has an opening formed in an upper portion at a position corresponding to the silicon wafer W on the substrate holding table 12. This opening is closed by a dielectric plate 13 made of quartz, Al₂O₃, or the like. The dielectric plate 13 is supported by a support portion 61 projected toward the inside of the vessel 11. On (on an outer side of) the dielectric plate 13, a slot plate 14 composed of a planar antenna to function as an antenna is provided. The slot plate 14 is made of a thin disk of a conductive material, for example, copper or aluminum plated with silver or gold, and has a large number of slits 14a. The disk may have rectangle shape or polygon shape. These slits 14a are arranged spirally or coaxially as a whole.

On (on an outer side of) the slot plate 14, disposed is a dielectric plate 15 made of, for example, quartz, alumina, aluminum nitride, or the like. This dielectric plate 15 is sometimes called a retardation plate or a wavelength shortening plate. On (on an outer side of) the dielectric plate 15, a cooling plate 16 is disposed. The cooling plate 16 has therein a refrigerant path 16a in which a refrigerant flows. Further, a rectangular waveguide 18 and a coaxial waveguide 19 which introduce a microwave of, for example, 2.45 GHz generated by a microwave supply device 17 are provided in an upper edge center of the process vessel 11. The coaxial waveguide 19 is composed of an outer conductor 19a and an inner conductor 19b. In this embodiment, these dielectric plate 13 and slot plate 14 constitute a plasma generating part. The aforesaid microwave is introduced into the process vessel 11 through the slot plate 14 and the dielectric plate 13 to generate plasma.

Above the silicon wafer W in the process vessel 11, a plasma baffle plate 20 as a partition plate made of quartz, alumina, or metal is disposed. By this plasma baffle plate 20, a first space S1 and a second space S2 are formed.

The plasma baffle plate 20 is held by a quartz liner 21 provided on an inner wall of the process vessel 11. The plasma baffle plate 20 may be directly supported by sidewalls of the process vessel 11. Details of the plasma baffle plate 20 will be described later. Around the substrate holding table 12, a gas baffle plate 28 made of aluminum is disposed. On an upper face of the gas baffle plate 28, a quartz cover 26 is provided. The gas baffle plate 28 is supported by a support portion 27.

On the inner wall of the process vessel 11, a gas nozzle 22 as a gas introducing part for introducing gas is provided. In this embodiment, a rare gas supply source 65, a nitriding gas supply source 66, and an oxidizing gas supply source 67 are prepared as gas supply sources, and they are connected to the gas nozzle 22 via valves 65a, 66a, 67a, mass flow controllers 65b, 66b, 67b, and valves 65c, 66c, 67c, respectively.

A flow rate of gas supplied from the gas nozzle 22 is controlled by the mass flow controllers 65b, 66b, 67b. In the sidewalls of the process vessel 11, a refrigerant path 24 is formed to surround the entire vessel.

A controller 52 controls ON-OFF and output control of the microwave supply device 17, the flow rate adjustment by the mass flow controllers 65b, 66b, 67b, the adjustment of an exhaust amount of the exhaust device 51, the heater function of the substrate holding table 12, and the like so as to allow the plasma processing apparatus 10 to perform optimum processing.

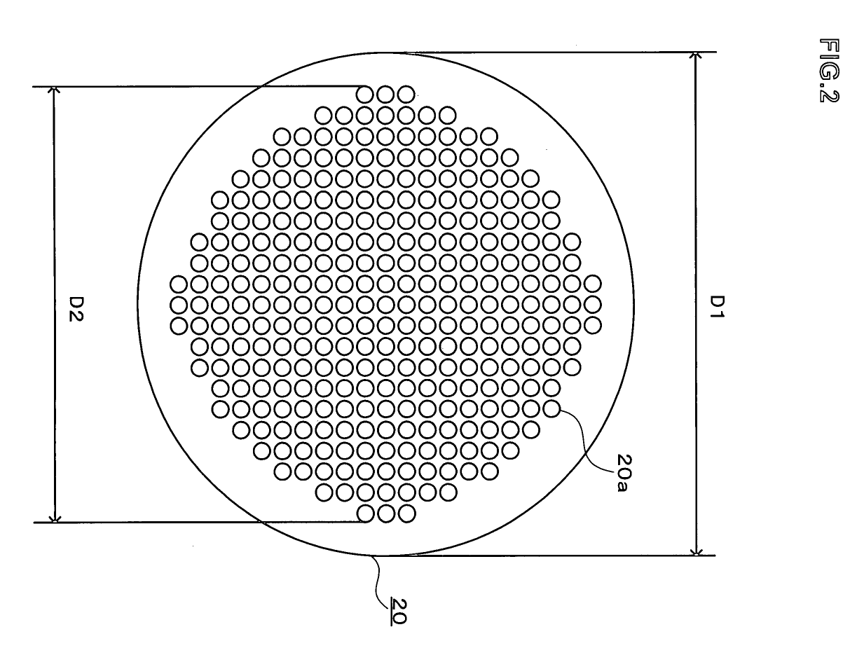

FIG. 2 shows a structure of the plasma baffle plate 20. The plasma baffle plate 20 is a disk-shaped plate with a thickness of 3 mm to 7 mm (for example, about 5 mm) and a large number of openings 20a are formed in the vicinity of a center thereof. It should be noted that the size, arrangement, and so on of the openings 20a in the drawing are schematically shown, and it goes without saying that they are different from those in actual use in some cases.

For forming the plasma baffle plate 20, for example, quartz, aluminum, alumina, silicon, metal, or the like is usable. As for the position of the plasma baffle plate 20, its height from a surface of the silicon wafer W is defined as H2 (20 mm to 50 mm, for example, 30 mm) and its distance from a lower face of the slot plate 14 is defined as H1 (40 mm to 110 mm, for example, 80 mm). If the plasma baffle plate 20 is too close to the surface of the silicon wafer W, uniform oxidation processing, nitridation processing, or oxynitridation processing is obstructed. On the other hand, if the plasma baffle plate 20 is too far from the surface of the silicon wafer W, plasma density lowers, which makes the oxidation/nitridation processing difficult to progress.

For example, when the silicon wafer W with a diameter of about 200 mm is to be processed, the plasma baffle plate 20 can have a diameter D1 of 360 mm and an area where the openings 20a are arranged can have a diameter D2 of 250 mm. When the silicon wafer W with a diameter of about 300 mm is to be processed, D1 and D2 are appropriately changed according to the size of the silicon wafer W. Further, in order to realize uniform processing on the surface of the silicon wafer W, it is preferable that a value of D2 is set according to the distance H2 of the plasma baffle plate 20 from the silicon wafer W, and the value of D2 is preferably, for example, 150 mm or larger.

A diameter of each of the openings 20a formed in the plasma baffle plate 20 can be set to 2.5 mm to 10 mm. For example, when the diameter of each of the openings 20a is set to 2.5 mm, the number thereof can be about 1000 to about 3000. When the diameter of each of the openings 20a is set to 5.0 mm or 10.0 mm, the number thereof can be about 300 to about 700. A laser machining method can be adopted for forming the openings 20a. Note that the shape of the openings 20a is not limited to a circle but may be a slit shape. At this time, an open area of each of the openings 20a is preferably 3 mm² to 450 mm². If the open area of the openings 20a is too large, ion density becomes high, so that damage cannot be reduced. On the other hand, if the open area is too small, plasma density becomes low, which makes oxidation processing, nitridation processing, or oxynitridation processing difficult to progress. Further, the open area of each of the openings 20a is preferably set in consideration of the thickness of the plasma baffle plate 20.

When plasma processing is performed by using the plasma processing apparatus 10 as structured above, the inside of the process vessel 11 is first exhausted through the exhaust ports 11A, 11B so that the process vessel 11 is set to a predetermined process pressure. Thereafter, oxidizing gas, nitriding gas, or oxidizing gas and nitriding gas, for example, O₂, N₂, NH₃, NO, NO₂, N₂O, or the like is introduced from the gas nozzle 22 together with inert gas such as, for example, argon, Kr, He, Xe, or Ne.

A microwave with a frequency of several GHz, for example, 2.45 GHz supplied through the coaxial waveguide 19 is introduced into the process vessel 11 through the dielectric plate 15, the slot plate 14, and the dielectric plate 13. Active species such as radicals and ions formed in the process vessel 11 through excitation by high-density microwave plasma reach the surface of the silicon wafer W through the plasma baffle plate 20. The radicals (gas) reaching the silicon wafer W flow along the surface of the silicon wafer W in a diameter direction (radial direction) to be quickly exhausted. This can prevent recombination of the radicals, which enables efficient and highly uniform substrate processing at low temperatures.

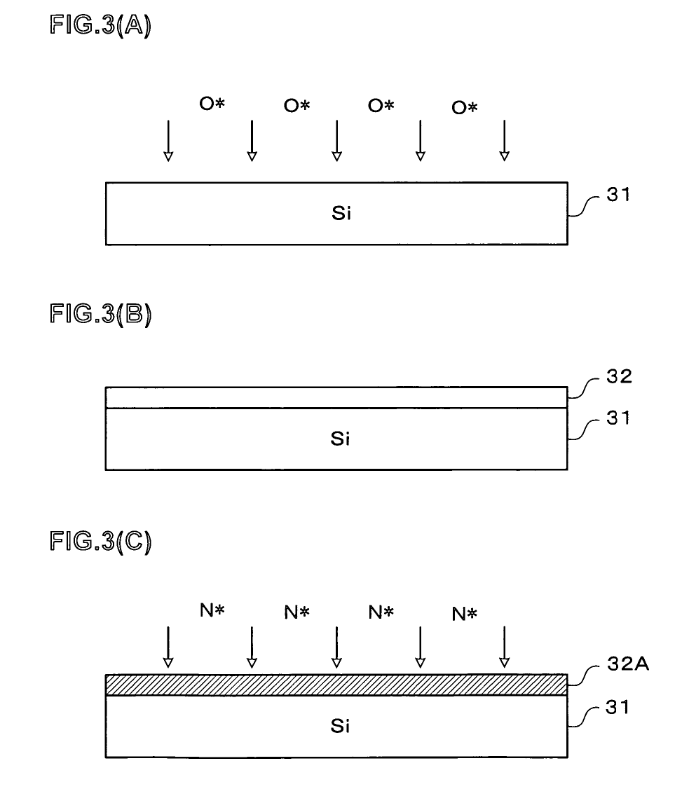

FIG. 3(A) to FIG. 3(C) show processes of substrate processing according to one embodiment, using the plasma processing apparatus 10 shown in FIG. 1.

A silicon substrate 31 (corresponding to the silicon wafer W) is put in the process vessel 11 and mixed gas of Kr and oxygen is introduced from the gas nozzle 22. This gas is excited by the microwave plasma, so that atomic oxygen (oxygen radicals) O* is formed. Then, as shown in FIG. 3(A), such atomic oxygen O* reaches a surface of the silicon substrate 31 through the plasma baffle plate 20.

The surface of the silicon substrate 31 is processed with the atomic oxygen, so that a silicon oxide film 32 with a thickness of 1.6 nm is formed on the surface of the silicon substrate 31, as shown in FIG. 3(B). The silicon oxide film 32 thus formed has a leakage current characteristic equivalent to that of a thermal oxide film formed at a high temperature of 1000° C. or higher even though being formed at a very low substrate temperature of about 400° C.

Next, in a process shown in FIG. 3(C), mixed gas of argon and nitrogen is supplied into the process vessel 11, the substrate temperature is set to 400° C., and a microwave is supplied, thereby exciting plasma.

In the process shown in FIG. 3(C), an inner pressure of the process vessel 11 is set to 0.7 Pa, argon gas is supplied at a flow rate of, for example, 1000 sccm, and nitrogen gas is supplied at a flow rate of, for example, 40 sccm. As a result, a surface of the silicon oxide film 32 is modified into a silicon nitride film 32A. Incidentally, the silicon oxide film 32 may be a thermal oxide film.

The process in FIG. 3(C) is continued for 20 seconds or more, for example, 40 seconds. As a result, the silicon nitride film 32A is formed, and when the growth passes a turnaround point, oxygen in the silicon oxide film 32 under the silicon nitride film 32A starts entering the inside of the silicon substrate 31. Turnaround is a phenomenon that as the surface of the silicon oxide film is being modified into the silicon nitride film, at first, an electrical film thickness (Equivalent Oxide Thickness) of the entire film decreases and a leakage current value also decreases compared with that of the film with the same conversion film thickness, but after a certain instance, the conversion film thickness of the entire film increases on the contrary. “The turnaround point” means an instant at which this phenomenon occurs.

In this embodiment, owing to the plasma baffle plate 20 disposed in the process vessel 11, ion energy and plasma density are lowered when reaching the surface of the silicon wafer W. Specifically, electron density on the surface of the silicon wafer W is controlled to be 1e+7 (electrons/cm³) to 5e+9 (electrons/cm³). Accordingly, the density of ions which are thought to damage the silicon oxide film 32 and the nitride film 32A lowers, so that less damage is given to the silicon oxide film 32 and the nitride film 32A.

Further, when the electron density on the surface of the silicon wafer W is controlled, the electron density can be lowered by, for example: (a) making the openings diameter of the plasma baffle plate 20 small; (b) making an interval between the plasma baffle plate 20 and the surface of the wafer W large; and (c) making the thickness of the plasma baffle plate 20 large.

Further, the gas reaching the silicon wafer W after passing through the openings 20a of the plasma baffle plate 20 increases in velocity on the wafer W. Specifically, the velocity of the gas on the surface of the silicon wafer W is controlled to be 1e−2 (m/sec) to 1e+1 (m/sec). As a result, a partial pressure of oxygen on the surface of the silicon wafer W lowers and thus an amount of the oxygen getting out of the nitride film 32A to the surface side of the silicon wafer W increases, so that the increase in thickness of the nitride film 32A is suppressed. It can be thought that the oxygen thus gets out of the nitride film 32A because of an oxygen concentration gradient between the nitride film 32A and the surface side of the silicon wafer W. The size of the openings 20a is adjusted for such control of the gas velocity, and the velocity gets higher as the size of the openings 20a is made smaller.

Further, the plasma processing apparatus 10 is capable of generating high-density plasma with lower power since it uses the slot plate 14 to generate plasma by the microwave, and also from this viewpoint, the plasma processing apparatus 10 is capable of executing processing with extremely little damage to the substrate.

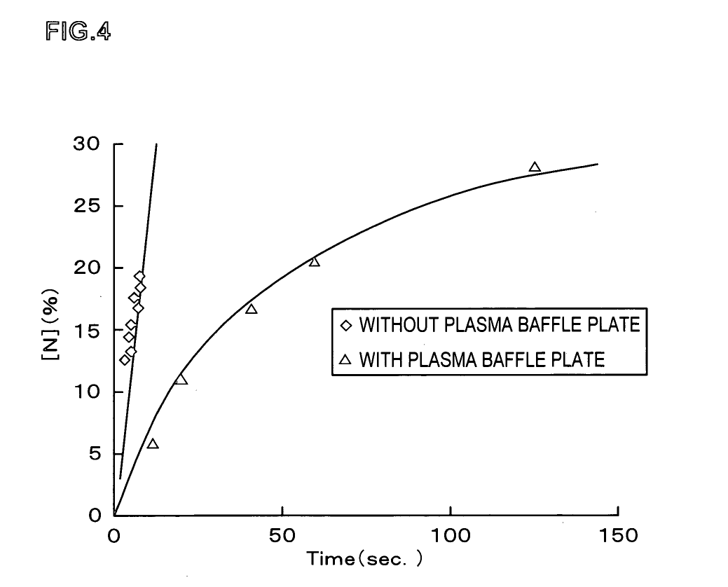

Next, results of nitridation processing applied to silicon substrates with the use of the plasma processing apparatus 10 will be shown in FIG. 4 to FIG. 6. In order to verify the effects of the present invention, results of comparison with a conventional plasma processing apparatus not having the plasma baffle plate 20 are also shown. Conditions of the processing are as follows.

Specifically, substrate temperature is 400° , power of a microwave is 1500 W, pressure in the process vessel is 50 mTorr to 2000 mTorr, a flow rate of nitrogen gas is 40 sccm to 150 sccm, and a flow rate of argon gas is 1000 sccm to 2000 sccm.

FIG. 4 shows process time vs. a ratio of nitrogen in a film. The ratio of nitrogen presents about 30% increase every 10 seconds in the conventional apparatus without any plasma baffle plate, but according to the apparatus having the plasma baffle plate as in the present invention, the ratio of nitrogen in the film presents gentle increase with time. Therefore, the present invention is capable of more easily controlling a nitridation rate.

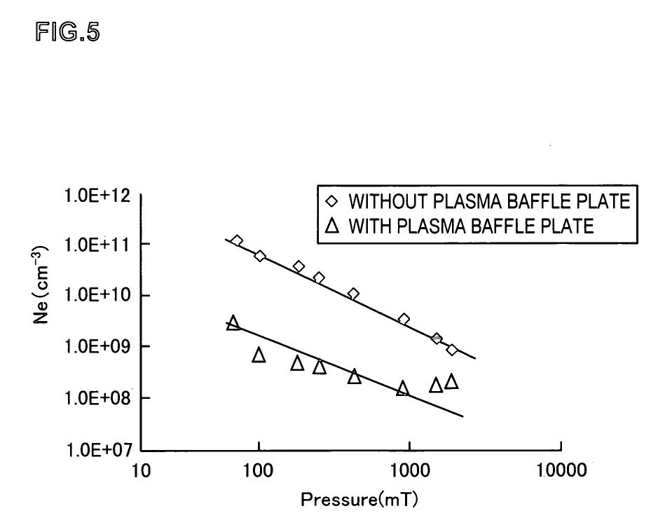

FIG. 5 shows how electron density changes under varied process pressure. It can be confirmed that the electron density is lower at all pressure values in the apparatus having the plasma baffle plate as in the present invention than that in the conventional apparatus. Therefore, it has been confirmed that according to the present invention, it is possible to reduce damage to the substrate.

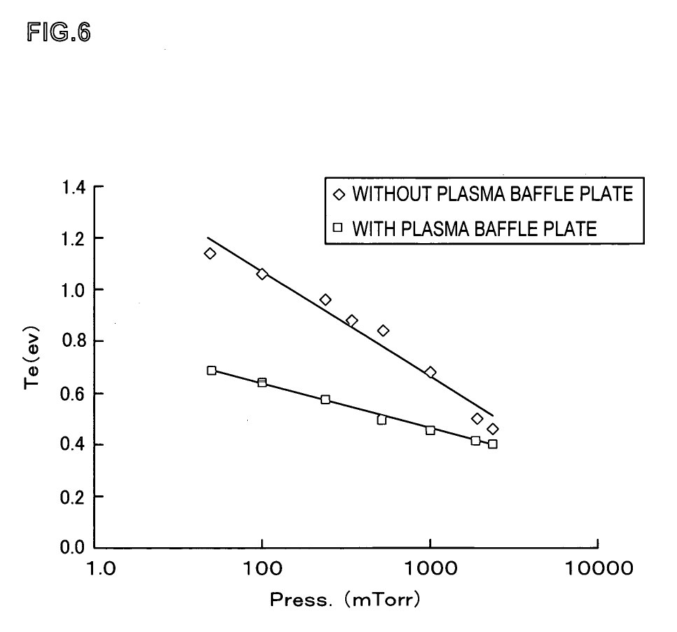

FIG. 6 shows how electron temperature changes under varied process pressure. It can be confirmed that the electron temperature is lower at all pressure values in the apparatus having the plasma baffle plate as in the present invention than in the conventional apparatus. Therefore, according to the present invention, it is possible to reduce charge-up damage to the substrate compared with the conventional apparatus.

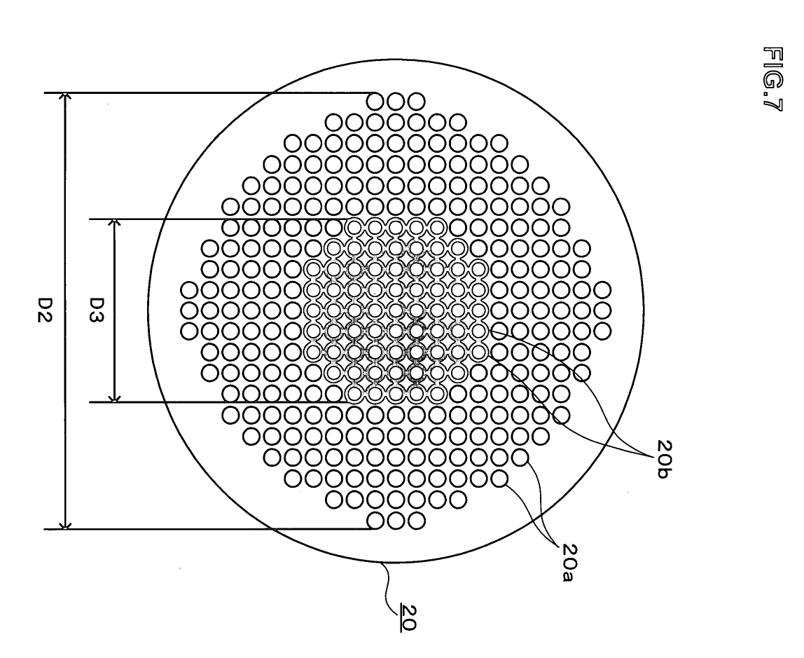

Incidentally, in the plasma baffle plate 20 used in the embodiment described above, the openings 20a all have the same size, but as shown in FIG. 7, openings 20b in a circular center area shown by a diameter D3 may be set smaller in size than openings 20a in an area on an outer side thereof shown by a diameter D2. For example, when the diameter of each of the openings 20a is 10 mm, the diameter of each of the openings 20b in the center portion may be set smaller than this, for example, 9.5 mm.

Thus making the openings 20b in the center portion smaller in size than the openings 20a positioned in the area on the outer side thereof makes it possible to reduce an amount of nitrogen radicals passing through the center portion, so that nitridation in the substrate center portion can be suppressed. Therefore, for example, in an apparatus or a process having such a characteristic that film thickness in a center portion tends to become larger, the use of the plasma baffle plate 20 whose openings 20b in the center portion are smaller in diameter as shown in FIG. 7 can suppress the growth of the film thickness in the center portion, resulting in uniform nitridation processing as the entire substrate, which can realize uniform film thickness.

Conversely, when the openings 20b in the center portion are made larger in size than the openings 20a positioned in the area on the outer side thereof, it is possible to promote nitridation in the center portion of the substrate since an amount of the nitrogen radicals passing through the center portion is larger than an amount of the nitrogen radicals passing through the other area. Therefore, for example, in an apparatus or a process having such a characteristic that film thickness in the center portion tends to become smaller than in the other area, the use of the plasma baffle plate 20 whose openings 20b in the center portion are thus larger in diameter than the openings 20a positioned in the area on the outer side thereof makes it possible to realize uniform film thickness.

Alternatively, the nitridation rate can be controlled by varying the thickness of the plasma baffle plate 20 itself. Specifically, when the thickness of the plasma baffle plate 20 is increased, the passage of nitrogen ions and radicals is controlled, so that the nitridation rate can be more suppressed.

Further, the plasma processing apparatus in the embodiment described above is structured as an apparatus applying nitridation processing, but this apparatus can be also used as an apparatus for oxidation processing or an apparatus for oxynitridation processing without any change made in the apparatus itself.

Similarly to the above-described case of the nitridation processing, the oxidation processing or the oxynitridation processing, the adoption of the plasma baffle plate can lower ion energy and ion density, so that damage to a silicon oxide film or a silicon oxynitride film can be reduced.

Further, in the above-described embodiment, the microwave plasma is used, but magnetron, inductive coupling, surface reflection, or ECR can be also utilized as a plasma source.

Moreover, the substrate is not limited to the aforesaid silicon substrate, but the present invention is applicable to, for example, a quadrangular glass substrate used for LCD.

The present invention is greatly effective for forming a nitride film, an oxide film, and an oxynitride film by plasma processing in manufacturing processes of a semiconductor device.

1. A plasma processing apparatus applying nitridation processing or oxidation processing to a substrate disposed in a process vessel by using plasma of gas containing at least one of nitrogen and oxygen, the apparatus comprising:
a partition plate provided between a plasma generating part and the substrate and having openings;
a first space formed by the plasma generating part and said partition plate; and
a second space formed by said partition plate and the substrate, wherein electron temperature of the plasma in said second space is 0.7 eV or lower.

2. The plasma processing apparatus as set forth in claim 1,
wherein the openings of said partition plate are formed in large number and are arranged to face the substrate, and
wherein an open area of each of the openings is 3 mm² to 450 mm².

3. The plasma processing apparatus as set forth in claim 1,
wherein said partition plate is 3 mm to 7 mm in thickness.

4. The plasma processing apparatus as set forth in claim 1,
wherein said partition plate is positioned 20 mm to 50 mm above a surface of the substrate.

5. The plasma processing apparatus as set forth in claim 1,
wherein the openings in said partition plate are all equal in diameter.

6. The plasma processing apparatus as set forth in claim 1,
wherein the openings in a center portion in said partition plate are smaller in diameter than the openings positioned on an outer side of the center portion.

7. The plasma processing apparatus as set forth in claim 1,
wherein each of the openings has a diameter of 2.5 mm to 10 mm.

8. The plasma processing apparatus as set forth in claim 1,
wherein the openings in a center portion in said partition plate is larger in diameter than the openings positioned on an outer side of the center portion.

9. The plasma processing apparatus as set forth in claim 1,
wherein the plasma generating part has an antenna.

10. The plasma processing apparatus as set forth in claim 9,
wherein the antenna is a planar antenna in which a plurality of slots are formed.

11. The plasma processing apparatus as set forth in claim 1,
wherein said partition plate is made of one of quartz, alumina, and silicon.

12. The plasma processing apparatus as set forth in claim 1,
wherein electron density of the plasma in said second space is 1e+7 (electrons/cm³) to 5e+9 (electrons/cm³).

13. A plasma processing apparatus applying nitridation processing or oxidation processing to a substrate disposed in a process vessel by using plasma of gas containing at least one of nitrogen and oxygen, the apparatus comprising:
a substrate holding table holding the substrate;
a dielectric disposed to close an opening formed in an upper portion of the process vessel;
an antenna disposed on an outer side of said dielectric;
a gas introducing part introducing the gas containing at least one of nitrogen and oxygen into the process vessel; and
a partition plate disposed between the substrate and said dielectric and having openings.

14. The plasma processing apparatus as set forth in claim 13,
wherein the openings of said partition plate are formed in large number and are arranged to face the substrate, and
wherein an open area of each of the openings is 3 mm to 450 mm.

15. The plasma processing apparatus as set forth in claim 13,
wherein said partition plate is positioned 20 mm to 50 mm above a surface of the substrate.

16. The plasma processing apparatus as set forth in claim 13,
wherein the antenna is a planar antenna in which a plurality of slots are formed.

17. The plasma processing apparatus as set forth in claim 13,
wherein said partition plate is made of one of quartz, alumina, and silicon.

18. The plasma processing apparatus as set forth in claim 13,
wherein electron temperature of the plasma is 0.7 eV or lower.

19. A plasma processing apparatus applying nitridation processing or oxidation processing to a substrate disposed in a process vessel by using plasma of gas containing at least one of nitrogen and oxygen, the apparatus comprising:
a substrate holding table holding the substrate;
a plasma generating part disposed above the process vessel and generating the plasma;
a gas introducing part introducing the gas containing at least one of nitrogen and oxygen into the process vessel; and
a partition plate disposed between said plasma generating part and the substrate and having openings.

20. The plasma processing apparatus as set forth in claim 19,
wherein the openings of said partition plate are formed in large number and are arranged to face the substrate, and
wherein an open area of each of the openings is 3 mm to 450 mm.

21. The plasma processing apparatus as set forth in claim 19,
wherein said partition plate is positioned 20 mm to 50 mm above a surface of the substrate.

22. The plasma processing apparatus as set forth in claim 19,
wherein said plasma generating part has an antenna.

23. The plasma processing apparatus as set forth in claim 22,
wherein the antenna is a planar antenna in which a plurality of slots are formed.

24. The plasma processing apparatus as set forth in claim 19,
wherein said partition plate is made of one of quartz, alumina, and silicon.

25. The plasma processing apparatus as set forth in claim 19,
wherein electron temperature of the plasma is 0.7 eV or lower.

26. A plasma processing apparatus applying substrate processing to a substrate disposed in a process vessel by using plasma of process gas, the apparatus comprising:
a substrate holding table holding the substrate;
a plasma generating part disposed above the process vessel and generating the plasma;
a gas introducing part introducing the process gas into the process vessel; and
a partition plate disposed between said plasma generating part and the substrate in the process vessel and having openings,
wherein said partition plate is made of one of quartz, alumina, and silicon.

27. The plasma processing apparatus as set forth in claim 26,
wherein the openings of said partition plate are formed in large number and are arranged to face the substrate, and
wherein an open area of each of the openings is 3 mm to 450 mm.

28. The plasma processing apparatus as set forth in claim 26,
wherein said partition plate is positioned 20 mm to 50 mm above a surface of the substrate.

29. The plasma processing apparatus as set forth in claim 26,
wherein said plasma generating part has an antenna.

30. The plasma processing apparatus as set forth in claim 29,
wherein the antenna is a planar antenna in which a plurality of slots are formed.

31. The plasma processing apparatus as set forth in claim 26,
wherein said partition plate is made of metal.

32. The plasma processing apparatus as set forth in claim 26,
wherein electron temperature of the plasma is 0.7 eV or lower.

33. A plasma processing apparatus applying substrate processing to a substrate disposed in a process vessel by using plasma of process gas, the apparatus comprising:
a substrate holding table holding the substrate;
a plasma generating part disposed above the process vessel and generating the plasma;
a gas introducing part introducing the process gas into the process vessel; and
a partition plate disposed between said plasma generating part and the substrate in the process vessel and having openings,
wherein the process vessel has a first space formed by said plasma generating part and said partition plate and a second space formed by said partition plate and said substrate holding table, and
wherein the substrate is processed in the second space by the plasma whose electron temperature is 0.7 eV or lower.

34. The plasma processing apparatus as set forth in claim 33,
wherein the openings of said partition plate are formed in large number and are arranged to face the substrate, and
wherein an open area of each of the openings is 3 mm² to 450 m².

35. The plasma processing apparatus as set forth in claim 33,
wherein said partition plate is positioned 20 mm to 50 mm above a surface of the substrate.

36. The plasma processing apparatus as set forth in claim 33,
wherein said plasma generating part has an antenna.

37. The plasma processing apparatus as set forth in claim 36,
wherein the antenna is a planar antenna in which a plurality of slots are formed.

38. The plasma processing apparatus as set forth in claim 33,
wherein said partition plate is made of one of quartz, alumina, and silicon.

39. The plasma processing apparatus as set forth in claim 33,
wherein said partition plate is made of metal.

40. The plasma processing apparatus as set forth in claim 33,
wherein electron density of the plasma in the second space is 1e+7 (electrons/cm³) to 5e+9 (electrons/cm³).

41. A plasma processing apparatus applying nitridation processing or oxidation processing to a substrate disposed in a process vessel by using plasma, the apparatus comprising
a partition plate disposed between a plasma generating part and the substrate and having openings,
wherein said partition plate is made of one of quartz, alumina, and silicon.

42. The plasma processing apparatus as set forth in claim 41,
wherein the openings of said partition plate are formed in large number and are arranged to face the substrate, and
wherein an open area of each of the openings is 3 mm to 450 mm .

43. The plasma processing apparatus as set forth in claim 41,
wherein said partition plate is positioned 20 mm to 50 mm above a surface of the substrate.

44. The plasma processing apparatus as set forth in claim 41,
wherein said plasma generating part has an antenna.

45. The plasma processing apparatus as set forth in claim 44,
wherein the antenna is a planar antenna in which a plurality of slots are formed.

46. The plasma processing apparatus as set forth in claim 41,
wherein electron temperature of the plasma is 0.7 eV or lower.

47. A plasma processing apparatus applying nitridation processing or oxidation processing to a substrate disposed in a process vessel by using plasma of gas containing at least one of nitrogen and oxygen, the apparatus comprising:
a partition plate disposed between a plasma generating part and the substrate and having openings;
a slot plate having a large number of slits and functioning as an antenna; and
a microwave generator supplying a microwave to said slot plate,
wherein the plasma is generated by supplying the microwave from said microwave generator into the process vessel via said slot plate.

48. The plasma processing apparatus as set forth in claim 47,
wherein the openings of said partition plate are formed in large number and are arranged to face the substrate, and
wherein an open area of each of the openings is 3 mm to 450 mm.

49. The plasma processing apparatus as set forth in claim 47,
wherein said partition plate is positioned 20 mm to 50 mm above a surface of the substrate.

50. The plasma processing apparatus as set forth in claim 47,
wherein said partition plate is made of one of quartz, alumina, and silicon.

51. The plasma processing apparatus as set forth in claim 47,
wherein electron temperature of the plasma is 0.7 eV or lower.

52. A plasma processing method of applying nitridation processing or oxidation processing to a substrate disposed in a process vessel by using plasma, the method comprising:
disposing, above the substrate, a partition plate having openings; and
controlling electron density on a surface of the substrate to be 1e+7 (electrons/cm³) to 5e+9 (electrons/cm³).

53. A plasma processing method of applying nitridation processing or oxidation processing to a substrate disposed in a process vessel by using plasma, the method comprising
controlling gas velocity on a surface of the substrate to be 1e⁻² (m/sec) to 1e+1 (m/sec).
